(19) United States
(12) Patent Application Publication
(10) Pub. No.: US 2025/0261338 A1
(43) Pub. Date: Aug. 14, 2025

(54) HEAT DISSIPATION MEMBER AND ELECTRONIC DEVICE

(71) Applicant: Denka Company Limited, Tokyo (JP)

(72) Inventors: Motoi NAGASAWA, Chuo Tokyo (JP); Hyojin NOGUCHI, Chuo Tokyo (JP)

(21) Appl. No.: 18/859,156

(22) PCT Filed: Apr. 13, 2023
(86) PCT No.: PCT/JP2023/015048

§ 371 Date: Oct. 22, 2024

(30) Foreign Application Priority Data
Apr. 28, 2022 (JP) 2022-074853

(51) Int. Cl. H05K 7/20; B22F 7/02; C22C 1/05; C22C 26/00

(52) U.S. Cl. CPC H05K 7/2039; B22F 7/02; C22C 1/05; C22C 26/00; B22F 2202/13; B22F 2301/10; B22F 2302/406; B22F 2304/058; B22F 2998/10; B22F 2999/00

(57) ABSTRACT

A heat dissipation member according to the present invention includes: a copper-diamond composite body in which a plurality of diamond particles are dispersed in a metal matrix containing copper; and a metal film that is bonded to at least one surface of the copper-diamond composite body, in which in at least one cross section of the heat dissipation member in a stacking direction, the copper-diamond composite body has a coarse particle layer containing the diamond particles that are coarse particles having a large particle diameter, and a fine particle layer containing the diamond particles that are fine particles having a smaller particle diameter than the coarse particles, and has a structure in which the fine particle layer is disposed closer to a bonding surface side between the copper-diamond composite body and the metal film than the coarse particle layer.

### TECHNICAL FIELD

The present invention relates to a heat dissipation member and an electronic device.

### BACKGROUND ART

Various heat dissipation members formed of a copper-diamond composite body have been developed thus far. As this kind of technique, for example, the technique described in Patent Document 1 is known. Regarding a composite material of a metal matrix and thermally conductive particles, Patent Document 1 describes that, since this composite material contains ceramic particles such as diamond particles or SiC particles, it is difficult to polish a surface of the composite material to be flat (paragraph 0012).

### RELATED DOCUMENT

### Patent Document

[Patent Document 1] International Publication No. WO2016/035796

### SUMMARY OF THE INVENTION

### Technical Problem

However, as a result of investigation by the present inventors, it was found that the heat dissipation member described in Patent Document 1 has room for improvement of thermal conductivity.

### Solution to Problem

As a result of further investigation by the present inventors, they found that in a copper-diamond composite body in which at least one surface is bonded to a metal film, when a fine particle layer containing fine diamond particles is formed on a bonding surface side on which the metal film is bonded, the thermal conductivity of the heat dissipation member can be improved, and completed the present invention.

According to one aspect of the present invention, a heat dissipation member and an electronic device described below are provided.

1. A heat dissipation member including:
a copper-diamond composite body in which a plurality of diamond particles are dispersed in a metal matrix containing copper; and
a metal film that is bonded to at least one surface of the copper-diamond composite body,
in which in at least one cross section of the heat dissipation member in a stacking direction, the copper-diamond composite body has
a coarse particle layer containing the diamond particles that are coarse particles having a large particle diameter, and
a fine particle layer containing the diamond particles that are fine particles having a smaller particle diameter than the coarse particles, and
has a structure in which the fine particle layer is disposed closer to a bonding surface side between the copper-diamond composite body and the metal film than the coarse particle layer.

2. The heat dissipation member according to 1,
in which when a particle size distribution of the diamond particles is measured using an image particle size distribution measuring device, in a volume particle size distribution of a particle diameter of the diamond particles,
a particle diameter D₅₀ corresponding to a cumulative value of 50% in the coarse particles is more than 100 μm and 300 μm or less, and
a particle diameter D₅₀ corresponding to a cumulative value of 50% in the fine particles is 100 μm or less.

3. The heat dissipation member according to 1 or 2, in which the copper-diamond composite body includes a stacked structure having a first fine particle layer and the coarse particle layer in this order in a layer thickness direction, or a stacked structure having a first fine particle layer, the coarse particle layer, and a second fine particle layer in this order in the layer thickness direction.

4. The heat dissipation member according to 3,
in which a thickness of the fine particle layer is 3 μm or more and 200 μm or less.

5. The heat dissipation member according to any one of 1 to 4,
in which a flatness of a bonding surface of the copper-diamond composite body to the metal film is 30 μm or less.

6. The heat dissipation member according to any one of 1 to 5,
in which a ten-point average height Rz in a bonding surface of the copper-diamond composite body to the metal film is 20 μm or less.

7. The heat dissipation member according to any one of 1 to 6,
in which a thermal conductivity of the copper-diamond composite body is 600 W/m·K or more.

8. The heat dissipation member according to any one of 1 to 7,
in which when a particle size distribution of the diamond particles is measured using an image particle size distribution measuring device, in a volume particle size distribution of a degree of sphericity of the diamond particles,
a degree of sphericity S₅₀ corresponding to a cumulative value of 50% in the coarse particles is 0.8 or more.

9. An electronic device including:
the heat dissipation member according to any one of 1 to 8; and
an electronic component provided over the heat dissipation member.

### Advantageous Effects of Invention

According to the present invention, a heat dissipation member having an excellent thermal conductivity and an electronic device including the heat dissipation member are provided.

### BRIEF DESCRIPTION OF THE DRAWINGS

FIG. 1 is a schematic cross-sectional view illustrating an example of a configuration of a heat dissipation member according to the present embodiment.

### DESCRIPTION OF EMBODIMENTS

Hereinafter, embodiments of the present invention will be described with reference to the drawings. In addition, in all the drawings, the same constituent elements are denoted by the same reference signs, and description thereof will not be repeated. In addition, the drawings are schematic views, and dimensional ratios in the drawings are different from actual dimensional ratios.

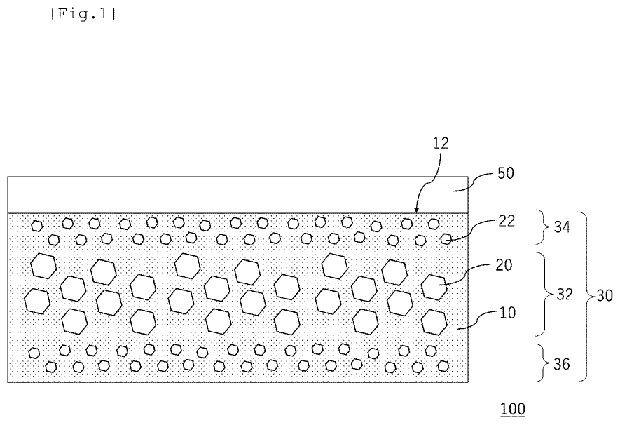

The summary of a heat dissipation member according to the present embodiment will be described with reference to FIG. 1.

FIG. 1 is a schematic cross-sectional view illustrating an example of a configuration of the heat dissipation member according to the present embodiment.

A heat dissipation member 100 according to the present embodiment includes: a copper-diamond composite body 30 in which a plurality of diamond particles 20 and 22 are dispersed in a metal matrix 10 containing copper; and a metal film 50 that is bonded to at least one surface of the copper-diamond composite body 30, and in at least one cross section of the heat dissipation member 100 in a stacking direction, the copper-diamond composite body 30 has a coarse particle layer 32 containing coarse diamond particles 20 having a large particle diameter, and a fine particle layer 34 containing fine diamond particles 22 having a smaller particle diameter than the coarse particles, and has a structure in which the fine particle layer 34 is disposed closer to a bonding surface (bonding interface 12) side between the copper-diamond composite body 30 and the metal film 50 than the coarse particle layer 32.

According to the findings of the present inventors, it has been found that since the smoothness of the surface of the copper-diamond composite body 30 (hereinafter, also simply referred to as “composite body”) can be improved with the fine particle layer 34 containing the fine diamond particles 22, the thickness of the metal film 50 formed on the above surface can be reduced and/or the adhesiveness to the metal film 50 can be increased, and as a result, the thermal conductivity of the heat dissipation member 100 including the composite body and the metal film 50 can be improved.

The detailed mechanism thereof is not clear. However, it is considered that, in a case where the film thickness of the metal film 50 is increased, the original high heat conduction characteristics of the composite body decrease, but by appropriately smoothing the surface of the composite body, the film thickness of the metal film 50 necessary for filling large irregularities on the surface can be reduced, the adhesiveness between the composite body and the metal film 50 can be increased, and a decrease in thermal conductivity of the overall heat dissipation member 100 formed of the copper-diamond composite body 30 and the metal film 50 can be suppressed.

In addition, according to the present embodiment, the coarse particle layer 32 containing the coarse diamond particles 20 is disposed in an inner layer of the composite body. The coarse diamond particles 20 in the coarse particle layer 32 can efficiently exhibit diamond's inherent heat conduction characteristics since (i) the aggregation is suppressed, (ii) the formation of pores due to the poor attachment of copper to the diamond interface can be suppressed, (iii) a decrease in thermal conductivity due to the increasing particle boundary surface is suppressed, or the like, compared to the fine diamond particles. Therefore, the thermal conductivity can be further improved by providing the fine particle layer 34 and the coarse particle layer 32.

The lower limit of the thermal conductivity of the heat dissipation member 100 is preferably 600 W/m·K or higher, more preferably 630 W/m·K or higher, and still more preferably 650 W/m·K or higher. Therefore, the heat dissipation characteristics of the heat dissipation member increase.

Meanwhile, the upper limit of the thermal conductivity of the heat dissipation member 100 is not particularly limited, and is preferably 950 W/m·K or lower, more preferably 900 W/m·K or lower, and still more preferably 870 W/m·K or lower.

The configuration of the heat dissipation member according to the present embodiment will be described in detail.

The heat dissipation member 100 includes the copper-diamond composite body 30 and the metal film 50.

### (Copper-Diamond Composite Body)

The copper-diamond composite body 30 includes the metal matrix 10 containing copper and the plurality of diamond particles 20 and 22 present in the metal matrix 10.

The lower limit of the thermal conductivity of the copper-diamond composite body 30 is preferably 600 W/m·K or higher, more preferably 630 W/m·K or higher, and still more preferably 650 W/m·K or higher. Therefore, the heat dissipation characteristics of the heat dissipation member increase.

Meanwhile, the upper limit of the thermal conductivity of the copper-diamond composite body 30 is not particularly limited, and is preferably 950 W/m·K or lower, more preferably 900 W/m·K or lower, and still more preferably 870 W/m·K or lower.

The shape and size of the copper-diamond composite body 30 can be appropriately set depending on uses.

Examples of the shape of the copper-diamond composite body 30 include a flat shape, a block shape, and a rod shape.

The metal matrix 10 may contain copper or may contain other high thermal conductivity metals excluding copper. That is, the metal matrix 10 is formed of a copper phase and/or a copper alloy phase.

As a main component in the metal matrix 10, copper is preferable from the viewpoint of thermal conductivity or costs.

The lower limit of the content of copper as a main component with respect to 100 mass % of the metal matrix 10 is preferably 50 mass % or more, more preferably 60 mass % or more, still more preferably 70 mass % or more, particularly preferably 80 mass % or more, and most preferably 90 mass or more. Therefore, a good thermal conductivity of copper and a copper alloy can be utilized, the same copper as the matrix can be used as a surface layer to ensure brazing properties and surface smoothness, and the formation of other surface coating layers can be omitted.

The upper limit of the content of copper as a main component with respect to 100 mass % of the metal matrix 10 is not particularly limited, and may be 100 mass % or less or 99 mass % or less.

Examples of other high thermal conductivity metals include silver, gold, and aluminum. These may be used alone, or two or more thereof may be used in combination. When copper and other high thermal conductivity metals are used in combination, an alloy or a composite material formed of copper and other high thermal conductivity metals can be used.

In the metal matrix 10, a metal or the like other than the high thermal conductivity metals is allowed within a range where the effect of the present invention does not deteriorate.

In addition, when a copper alloy is used as the metal matrix 10, examples of the copper alloy include CuAg, CuAl, CuSn, CuZr, and CrCu.

The metal matrix 10 is, for example, a sintered compact of a metal powder containing copper (and other high thermal conductivity metals as necessary). In the present embodiment, the metal matrix 10 is formed of a sintered compact in which at least a part of the plurality of diamond particles 20 and 22 is embedded.

The copper-diamond composite body 30 has at least the coarse particle layer 32 and the fine particle layer 34 (first fine particle layer).

In the heat dissipation member 100 according to the present embodiment, the fine particle layer 34 containing the fine diamond particles 22 is disposed on the surface (bonding interface 12) side of the copper-diamond composite body 30. With the fine particle layer 34, the surface roughness of the surface of the composite body can be reduced, that is, the surface of the composite body can be smoothed, as compared with a case where the coarse particle layer 32 containing the coarse diamond particles 20 is formed on the surface.

An example of the copper-diamond composite body 30 may have a stacked structure having the first fine particle layer (fine particle layer 34) and the coarse particle layer 32 in this order in a layer thickness direction, or may have the first fine particle layer (fine particle layer 34), the coarse particle layer 32, and the second fine particle layer (fine particle layer 36) in this order in the layer thickness direction. That is, the copper-diamond composite body 30 may be formed of a sintered compact having at least a two-layer structure or a three-layer structure. Therefore, it is possible to further improve the thermal conductivity in the thickness direction.

The degrees of sphericity and the particle diameters of the diamond particles 20 and 22 are measured in the following procedure.

The particle size distributions of the diamond particles 20 and 22 are measured using an image particle size distribution measuring device (for example, Morphologi 4, manufactured by Malvern Panalytical Ltd.). The particle size distribution includes a shape distribution and a particle diameter distribution.

A volume particle size distribution of the degree of sphericity and a volume particle size distribution of the particle diameter are created from the obtained particle size distribution.

In the volume particle size distribution of the degree of sphericity of the diamond particles 20, a degree of sphericity corresponding to a predetermined cumulative value and a particle diameter corresponding to a predetermined cumulative value are obtained.

Here, the degree of sphericity and the particle diameter are defined as follows.

Degree of sphericity: a ratio between the circumferential length of a circumference having the same area as a projected object and the circumferential length of the object

Particle diameter: the maximum length at two points on the contour of a particle image

The upper limit of a particle diameter D₅₀ corresponding to a cumulative value of 50% in the coarse diamond particles 20, measured in the above-described procedure, is, for example, 300 μm or less, preferably 270 μm or less, more preferably 250 μm or less, still more preferably 220 μm or less, particularly preferably 200 μm or less, and most preferably 180 μm or less. As a result, the filling density of the diamond particles 20 is increased, and the thermal conductivity of the composite body is increased.

The lower limit of the particle diameter D₅₀ of the coarse diamond particles 20 is more than 100 μm.

The lower limit of a degree of sphericity S₅₀ corresponding to a cumulative value of 50% in the coarse diamond particles 20, measured in the above-described procedure, is, for example, 0.8 or more, preferably 0.85 or more, more preferably 0.87 or more, and still more preferably 0.9 or more. As a result, the filling density of the diamond particles 20 is increased, and the thermal conductivity of the composite body is increased.

Meanwhile, the upper limit of the degree of sphericity S₅₀ of the coarse diamond particles 20 is not particularly limited, and may be, for example, 1.0 or less or 0.99 or less.

The upper limit of a particle diameter D₅₀ corresponding to a cumulative value of 50% in the fine diamond particles 22, measured in the above-described procedure, is, for example, 100 μm or less, preferably 50 μm or less, more preferably 30 μm or less, and still more preferably 10 μm or less. Therefore, the surface smoothness of the composite body can be improved, and the thermal conductivity of the heat dissipation member 100 can be increased.

The lower limit of the particle diameter D₅₀ of the fine diamond particles 22 is not particularly limited, and may be, for example, more than 0.1 μm.

A linking structure in which one diamond particle 20 is in contact with the other diamond particles 20 may be provided in the coarse particle layer 32. In the linking structure, at least one or more, two or more, or four or more diamond particles 20 may be continuously in contact with each other. Therefore, the thermal conductivity of the heat dissipation member 100 can be improved.

The above-described linking structure is found in at least one cross section of the heat dissipation member 100 in the thickness direction.

The upper limit of the thickness of the fine particle layer 34 and/or the fine particle layer 36 is, for example, 200 μm or less, preferably 150 μm or less, and more preferably 100 μm or less. Therefore, it is possible to suppress a decrease in thermal conductivity of the heat dissipation member 100.

Meanwhile, the lower limit of the thickness of the fine particle layer 34 and/or the fine particle layer 36 is, for example, 3 μm or more, preferably 5 μm or more, and more preferably 8 μm or more. Therefore, the surface smoothness of the composite body can be improved.

The upper limit of the flatness of the bonding surface (bonding interface 12) of the copper-diamond composite body 30 to the metal film 50 is, for example, 30 μm or less, preferably 20 μm or less, and more preferably 10 μm or less. Therefore, the thermal conductivity of the heat dissipation member 100 can be increased.

Meanwhile, the lower limit of the above-described flatness is not particularly limited, and may be 1 μm or more.

The flatness can be calculated based on JIS B 0621: 1984 using a digital microscope.

The upper limit of a ten-point average height Rz in the bonding surface (bonding interface 12) between the copper-diamond composite body 30 and the metal film 50 is, for example, 20 μm or less, preferably 10 μm or less, and more preferably 5 μm or less. Therefore, the thermal conductivity of the heat dissipation member 100 can be increased.

Meanwhile, the lower limit of the ten-point average height Rz is not particularly limited, and may be, for example, 0.1 μm or more, 0.5 μm or more, or 1 μm or more.

The ten-point average height Rz can be calculated based on JIS B 0601: 2013.

A transition region where both the diamond particles 20 and the diamond particles 22 are present may be formed between the fine particle layer 34 and the coarse particle layer 32 and/or between the fine particle layer 36 and the coarse particle layer 32. Therefore, it is possible to suppress a decrease in diamond's inherent heat conduction characteristics in the composite body.

The transition region can be confirmed with a SEM cross-sectional image of the heat dissipation member 100 in the thickness direction.

The diamond particles 20 and 22 include at least any one of non-coated diamond particles having no metal-containing coating layer on the surface or coated diamond particles having a metal-containing coating layer on the surface. From the viewpoint of dispersibility and an improvement in adhesiveness between the diamond and the metal particles, coated diamond particles are more preferable.

The lower limit of the total volume ratio of the diamond particles 20 and the diamond particles 22 in the copper-diamond composite body 30 is preferably 10 vol % or more, more preferably 20 vol % or more, and still more preferably 30 vol % or more. Therefore, the thermal conductivity of the copper-diamond composite body 30 can be increased.

Meanwhile, the upper limit of the total volume ratio of the diamond particles 20 and the diamond particles 22 in the copper-diamond composite body 30 is, for example, preferably 80 vol % or less, more preferably 70 vol % or less, and still more preferably 60 vol % or less. This can suppress large pores remaining in the copper-diamond composite 30, due to decrease in attachment of the copper powder to the peripheries of the diamond particles 20 and other factors, and thus realize a structure having excellent manufacturing stability.

When coated diamond particles are used as the diamond particles 20, the metal-containing coating layer in the coated diamond particles may contain molybdenum, tungsten, chromium, zirconium, hafnium, vanadium, niobium, tantalum, and alloys thereof. These may be used alone, or two or more thereof may be used in combination. In addition, the metal-containing coating layer is configured to cover at least a part or the whole of the particle surface.

### (Metal Film)

The metal film 50 only needs to be formed on at least one surface of the copper-diamond composite body 30, and may be formed on each of both surfaces of the flat copper-diamond composite body 30, for example.

The metal film 50 may contain one or two or more selected from the group consisting of copper, silver, gold, aluminum, nickel, zinc, tin, and, magnesium. The metal film 50 preferably contains the same metal as the metal as the main component in the metal matrix 10, and more preferably contains at least copper or a copper alloy.

The content of copper as a main component with respect to 100 mass % of the metal film 50 is preferably 50 mass % or more, more preferably 60 mass % or more, still more preferably 70 mass % or more, particularly preferably 80 mass % or more, and most preferably 90 mass % or more.

The upper limit of the content of copper as a main component with respect to 100 mass % of the metal film 50 is not particularly limited, and may be 100 mass % or less or 99 mass % or less.

The upper limit of the film thickness of the metal film 50 is preferably 150 μm or less, more preferably 120 μm or less, and still more preferably 100 μm or less. Therefore, the thermal conductivity of the heat dissipation member can be increased.

Meanwhile, the lower limit of the film thickness of the metal film 50 is preferably 10 μm or more, more preferably 15 μm or more, and still more preferably 20 μm or more. Therefore, the adhesion strength with the composite body and the durability of the metal film itself can be increased.

The metal film 50 is obtained, for example, using a sputtering method or a plating method.

The average crystal particle diameter of the metal in the metal film 50 is preferably 5 nm or more and 50 nm or less, more preferably 10 nm or more and 40 nm or less, and still more preferably 20 nm or more and 30 nm or less. The average crystal particle diameter can be calculated from the number of crystal particles in a range of 1 μm² of a structure obtained using a transmission electron microscope (TEM).

An electronic device according to the present embodiment includes the above-described heat dissipation member and an electronic component that is provided over the heat dissipation member.

Examples of the electronic component include a semiconductor element. Specific examples of the semiconductor element include a power semiconductor, an image display element, a microprocessor unit, and a laser diode.

The heat dissipation member is used as a heat sink, a heat spreader, or the like. The heat sink dissipates heat generated during an operation of a semiconductor element to an external space, and the heat spreader spreads heat generated from a semiconductor element to other members.

The electronic component may be installed in the heat dissipation member directly or indirectly through a ceramic substrate or the like.

An example of a method of manufacturing the heat dissipation member according to the present embodiment will be described.

An example of the method of manufacturing the heat dissipation member includes a raw material mixing step, a sintering step, and a film forming step.

In the raw material mixing step, a copper-diamond mixture A containing a metal powder containing copper and coarse diamond particles 20 and a copper-diamond mixture B containing a metal powder containing copper and fine diamond particles 22 are produced. In the production of the mixtures, various methods such as a dry method and a wet method can be applied for mixing.

In an example of the production of the copper-diamond mixture A, a metal powder containing copper such as a copper powder and coarse diamond particles 20 are mixed in a dry manner to obtain a powdery copper-diamond mixture A.

In an example of the production of the copper-diamond mixture B, a metal powder containing copper such as a copper powder and fine diamond particles 22 are mixed in a dry manner to obtain a powdery copper-diamond mixture B.

In addition, in an example of the production of the copper-diamond mixture B, a metal powder containing copper such as a copper powder and fine diamond particles 22 are mixed in a wet manner in a solvent to obtain a copper-diamond paste (also simply referred to as a paste).

In the production of the paste, known methods can be used for mixing, and for example, a mixing method using a roll can be adopted.

The solvent is not particularly limited as long as it can disperse the metal powder and the diamond particles 22, and an alcohol-based solvent such as terpineol, ethylene glycol, glycerin, or texanol, a glycol ether-based solvent such as butyl carbitol, a glycol ester-based solvent such as butyl carbitol acetate, a ketone-based solvent such as methyl ethyl ketone or isophorone, or the like may be used.

The copper-diamond paste may contain an additive such as a binder resin as necessary. Examples of the binder resin include an amino resin, a ketone resin, ethyl cellulose, and nitrocellulose.

The viscosity of the copper-diamond paste is measured at 25° C. using a B-type viscometer, and is, for example, 10 Pa·s to 1,000 Pa·s, preferably 30 Pa·s to 500 Pa·s, and more preferably 50 Pa·s to 300 Pa·s.

The metal powder may contain a copper powder and/or a copper alloy powder.

An average particle diameter D₅₀ of the metal powder may be, for example, 0.1 μm to 3 μm, 0.2 μm to 2 μm, or 3 μm to 1 μm.

In the present specification, the term “to” indicates that the upper limit value and the lower limit value are included, unless particularly stated otherwise.

In the firing step, the copper-diamond mixture A containing the coarse diamond particles 20 is overlapped with a copper-diamond film containing the fine diamond particles 22 and they are fired to obtain a composite sintered compact (copper-diamond composite body 30) having at least a two-layer structure. A dry film formed by applying the obtained copper-diamond paste onto a copper sheet and drying the copper-diamond paste is used as the copper-diamond film.

In addition, in the production from the mixed powder of copper and fine diamond particles provided by mixing in a dry manner, the copper-diamond mixture B may be filled on upper and lower surfaces where a mixed layer of copper and coarse diamond particles is formed so that a desired firing thickness is obtained, and thus a three-layer structure may be formed and a sintered compact may be obtained.

In an example of the firing step, both sides of the copper-diamond mixture may be sandwiched between the copper-diamond films and they may be fired to obtain a sintered compact having a three-layer structure.

The firing temperature can be appropriately selected depending on the metal species contained in the metal powder. The firing temperature of the copper powder is preferably 800° C. or higher and 1,100° C. or lower, and more preferably 850° C. or higher and 1,000° C. or lower. By adjusting the firing temperature to 800° C. or higher, the copper-diamond composite body is densified and a desired thermal conductivity can be obtained. By adjusting the firing temperature to 1, 100° C. or lower, deterioration of the interfaces of the diamond particles caused by graphitization can be suppressed, and a decrease in thermal conductivity of the diamond itself can be prevented.

The firing time is not particularly limited, and is preferably 5 minutes or longer and 3 hours or shorter, and more preferably 10 minutes or longer and 2 hours or shorter. By adjusting the firing time to 5 minutes or longer, the copper-diamond composite body is densified and a desired thermal conductivity can be obtained. By adjusting the firing time to 3 hours or shorter, it is possible to suppress the formation of a carbide between the diamond in the coated diamond particles and the metal with which the surfaces are coated or an increase in film thickness, leading to a decrease in thermal conductivity due to phonon scattering or cracks occurring due to a difference in linear expansion coefficient. In addition, the productivity of the composite body can be increased.

In the firing step, a pressureless sintering method or a pressure sintering method may be used, and a pressure sintering method is preferable to obtain a dense composite body.

Examples of the pressure sintering method include hot press sintering, spark plasma sintering (SPS), and hot isostatic pressure (HIP) sintering. In hot press sintering or SPS sintering, the pressure is preferably 10 MPa or higher, and more preferably 30 MPa or higher. Meanwhile, in hot press sintering or SPS sintering, the pressure is preferably 100 MPa or lower. By adjusting the pressure to 10 MPa or higher, the copper-diamond composite body is densified and a desired thermal conductivity can be obtained. By adjusting the pressure to 100 MPa or lower, it is possible to prevent diamond's fracture, which increases the diamond interfaces or decreases the adhesiveness between a diamond fracture surface and metal, and thus leads to a decrease in thermal conductivity of the diamond itself.

In the film forming step, the metal film 50 is formed on at least a part of the surface of the copper-diamond composite body 30.

As a method of forming the metal film, general methods such as a sputtering method, a plating method, and a pressure co-firing method using copper foil or a copper sheet may be adopted. However, a sputtering method may be used to reduce the film thickness.

In addition, at least a part of the surface of the metal film may be subjected to surface grinding and polishing. As a result, the surface smoothness of the metal film after the film forming step can be improved.

In addition, a smoothing step may be performed for the composite sintered compact after the firing step as necessary. In such a smoothing step, at least a part of the surface of the composite sintered compact is ground and polished.

In addition, an annealing step may be added and performed for the composite sintered compact between the firing step and the smoothing step.

In addition, a step of performing processing such as shaping or perforating on the copper-diamond composite body may be performed before the film forming step.

The embodiments of the present invention have been described above; however, these are examples according to the present invention, and it is possible to adopt various configurations other than the above. In addition, the present invention is not limited to the embodiments described above and modifications, improvements, and the like are included in the present invention in a range in which it is possible to achieve the purpose of the present invention.

### EXAMPLES

Hereinafter, the present invention will be described in detail with reference to Examples. However, the present invention is not limited to the description of these Examples.

### <Production of Composite Body and Heat Dissipation Member>

### Example 1

A copper powder (average particle diameter D₅₀: 0.5 μm) and diamond particles A (coated with Mo) shown in Table 1 were weighed at 50 vol %:50 vol %, and the weighed powders were mixed in terpineol (solvent) to produce a paste using three rolls.

The viscosity of the prepared paste was 150 Pa·s as a result of measurement at 25° C. using a B-type viscometer.

The obtained paste was applied onto copper foil and dried at 80° C. for 1 hour to form a dry film. Two sets of copper foil with a dry film were prepared.

The thickness of the dry film of the paste on the copper foil was confirmed with a SEM cross-sectional image in a thickness direction, and the result was 15 μm.

A copper powder (average particle diameter D₅₀: 0.5 μm) and diamond particles B (coated with Mo) shown in Table 1 were weighed at 50 vol %:50 vol %, and the weighed powders were uniformly mixed using a V-shape mixer to obtain a mixture (raw material mixing step).

Next, both sides of the obtained mixture were sandwiched between copper foils with a dry film, and the copper foils were peeled off to fill a firing mold with a three-layer structure of dry film/mixture/dry film. Using an SPS firing device, the three-layer structure in the firing mold was sintered by heating at 900° C. for 1 hour under a pressure condition of 30 MPa to obtain a disk-like composite sintered compact having a three-layer structure (copper-diamond composite body) (sintering step).

The composite sintered compact having a three-layer structure had an outer diameter of 30 mmϕ and a thickness of 3 mm.

A particle size distribution (shape distribution/particle diameter distribution) of each of the diamond particles A and B as raw materials was measured using an image particle size distribution measuring device (Morphologi 4, manufactured by Malvern Panalytical Ltd.).

A degree of sphericity S₅₀ corresponding to a cumulative value of 50% in the volume particle size distribution of the degree of sphericity of the diamond particles, and a particle diameter D₅₀ corresponding to a cumulative value of 50% in the volume particle size distribution of the particle diameter of the diamond particles were obtained. Each of these values was an average value of two measured values.

The degree of sphericity and the particle diameter were defined as follows.

Degree of sphericity: a ratio between the circumferential length of a circumference having the same area as a projected object and the circumferential length of the object

Particle diameter: the maximum length at two points on the contour of a particle image

As a result, the particle diameter D₅₀ in the diamond particles A used was 5 μm. In the diamond particles B, the degree of sphericity S₅₀ was 0.9, and the particle diameter D₅₀ was 200 μm.

In the copper-diamond composite body, a three-layer structure consisting of a first fine particle layer in which the fine diamond particles A were dispersed in the copper matrix/a coarse particle layer in which the coarse diamond particles B were dispersed in the copper matrix/a second fine particle layer in which the fine diamond particles A were dispersed in the copper matrix was confirmed with a SEM cross-sectional image in the thickness direction.

Each of the thicknesses of the first fine particle layer and the second fine particle layer obtained from the SEM cross-sectional image in the thickness direction was 12.3 μm.

The surface roughness and the flatness of the copper-diamond composite body on a surface (surface region ranging from the copper matrix to the diamond particles A) of the first fine particle layer were observed and measured using a digital microscope (VHX-8000, manufactured by Keyence Corporation). A ten-point average height Rz calculated based on JIS B 0601: 2013 was 2.5 μm, and a flatness calculated based on JIS B 0621:1984 was 5.3 μm.

In addition, the thermal conductivity of the surface of the copper-diamond composite body was measured using a laser flash method, and the result was 812 W/m·K. The measurement using the laser flash method was performed at room temperature after coating the sample surface with carbon.

Next, a Cu film having a thickness of 50 μm was formed using a sputtering method on each of both surfaces of the copper-diamond composite body, and a heat dissipation member formed of Cu film/copper-diamond composite body/Cu film was obtained (film forming step).

The thermal conductivity of the heat dissipation member was measured using a laser flash method, and the result was 765 W/m·K.

### Examples 2 to 4

A composite body and a heat dissipation member were obtained in the same manner as in Example 1, except that the particle diameter of the diamond particles, the degree of sphericity, and the thickness of the fine particle layer were changed according to the conditions shown in Table 1.

The same evaluation as that of Example 1 was performed on the obtained composite bodies and the obtained heat dissipation members.

TABLE 1

| | | | | | | Copper-Diamond Composite Body | | | | | |
|---|---|---|---|---|---|---|---|---|---|---|---|
| | Paste for Forming Fine | | | | | (First Fine Particle Layer/Coarse Particle | | | | | |
| | Particle Layer | | | | | Layer/Second Fine Particle Layer) | | | | Cu Film/Copper- | |
| | Diamond | Copper | | | | | | | Thicknesses of | Diamond Composite | |
| | Particles A | Powder | | Diamond Particles B | | | | | First Fine Particle | Body/Cu Film | |
| | Particle | Particle | | Particle | | Ten-Point | | Thermal | Layer/Second | | Thermal |
| | Diameter | Diameter | | Diameter | Degree of | Average | | Conduc- | Fine Particle | Cu Film | Conduc- |
| | D₅₀ | D₅₀ | Viscosity | D₅₀ | Sphericity | Height Rz | Flatness | tivity | Layer | Thickness | tivity |
| | (μm) | (μm) | (Pa · s) | (μm) | S₅₀ | (μm) | (μm) | (W/m · k) | (μm) | (μm) | (W/m · k) |
| Example 1 | 5 | 0.5 | 280 | 200 | 0.9 | 2.5 | 5.3 | 812 | 12.3/12.3 | 50 | 765 |
| Example 2 | 20 | 0.5 | 230 | 200 | 0.9 | 9.4 | 18.6 | 784 | 47.2/48.8 | 50 | 712 |
| Example 3 | 50 | 0.5 | 194 | 200 | 0.9 | 18.7 | 26.4 | 739 | 108/104 | 50 | 669 |
| Example 4 | 5 | 0.5 | 280 | 200 | 0.8 | 2.7 | 6.1 | 805 | 13.1/13.8 | 50 | 737 |

### Example 5

A copper powder (average particle diameter D₅₀: 0.5 μm) and diamond particles A (coated with Mo) shown in Table 2 were weighed at 50 vol %:50 vol %, and the weighed powders were uniformly mixed using a V-shape mixer to obtain a mixture A (raw material mixing step 1).

A copper powder (average particle diameter D₅₀: 0.5 μm) and diamond particles B (coated with Mo) shown in Table 2 were weighed at 50 vol %:50 volt, and the weighed powders were uniformly mixed using a V-shape mixer to obtain a mixture B (raw material mixing step 2).

Next, the obtained mixtures A and B were filled in a three-layer structure of mixture A/mixture B/mixture A in a firing mold. Using an SPS firing device, the three-layer structure in the firing mold was sintered by heating at 900° C. for 1 hour under a pressure condition of 30 MPa to obtain a disk-like composite sintered compact having a three-layer structure (copper-diamond composite body) (sintering step).

The composite sintered compact having a three-layer structure had an outer diameter of 30 mmϕ and a thickness of 3 mm.

In the copper-diamond composite body, a three-layer structure consisting of a first fine particle layer in which the fine diamond particles A were dispersed in the copper matrix/a coarse particle layer in which the coarse diamond particles B were dispersed in the copper matrix/a second fine particle layer in which the fine diamond particles A were dispersed in the copper matrix was confirmed with a SEM cross-sectional image in the thickness direction.

The thicknesses of the first fine particle layer and the second fine particle layer obtained from the SEM cross-sectional image in the thickness direction were 20.7 μm and 21.3 μm, respectively.

The surface roughness and the flatness of the copper-diamond composite body on a surface (surface region ranging from the copper matrix to the diamond particles A) of the first fine particle layer were observed and measured using a digital microscope (VHX-8000, manufactured by Keyence Corporation). A ten-point average height Rz calculated based on JIS B 0601: 2013 was 2.3 μm, and a flatness calculated based on JIS B 0621:1984 was 4.9 μm.

In addition, the thermal conductivity of the surface of the copper-diamond composite body was measured using a laser flash method, and the result was 801 W/m·K. The measurement using the laser flash method was performed at room temperature after coating the sample surface with carbon.

Next, a Cu film having a thickness of 50 μm was formed using a sputtering method on each of both surfaces of the copper-diamond composite body, and a heat dissipation member formed of Cu film/copper-diamond composite body/Cu film was obtained (film forming step).

The thermal conductivity of the heat dissipation member was measured using a laser flash method, and the result was 726 W/m·K.

### Examples 6 to 9

A composite body and a heat dissipation member were obtained in the same manner as in Example 5, except that the particle diameter of the diamond particles, the degree of sphericity, and the thickness of the fine particle layer were changed according to the conditions shown in Table 2.

The same evaluation as that of Example 5 was performed on the obtained composite bodies and the obtained heat dissipation members.

TABLE 2

| | | | | Copper-Diamond Composite Body | | | | | |
|---|---|---|---|---|---|---|---|---|---|
| | | | | (First Fine Particle Layer/Coarse Particle | | | | | |
| | | | | Layer/Second Fine Particle Layer) | | | | | |
| | Diamond | | | | | | Thicknesses | | |
| | Particles | | | Ten- | | | of First | | |
| | A | Diamond Particles B | | Point | | | Fine Particle | Cu Film/Copper-Diamond | |
| | Particle | Particle | | Average | | | Layer/Second | Composite Body/Cu Film | |
| | Diameter | Diameter | Degree of | Height | | Thermal | Fine Particle | Cu Film | Thermal |
| | D₅₀ | D₅₀ | Sphericity | Rz | Flatness | Conductivity | Layer | Thickness | Conductivity |
| | (μm) | (μm) | S₅₀ | (μm) | (μm) | (W/m · k) | (μm) | (μm) | (W/m · k) |
| Example | 5 | 200 | 0.9 | 2.3 | 4.9 | 801 | 20.7/21.3 | 50 | 726 |
| 5 | | | | | | | | | |
| Example | 20 | 200 | 0.9 | 4.7 | 16.5 | 774 | 50.5/53.2 | 50 | 703 |
| 6 | | | | | | | | | |
| Example | 20 | 200 | 0.9 | 4.8 | 17.2 | 785 | 189/194 | 50 | 722 |
| 7 | | | | | | | | | |
| Example | 50 | 200 | 0.9 | 17.4 | 28.8 | 747 | 104/112 | 50 | 668 |
| 8 | | | | | | | | | |
| Example | 5 | 200 | 0.8 | 2.6 | 5.4 | 789 | 22.4/20.1 | 50 | 721 |
| 9 | | | | | | | | | |

### Comparative Example 1

A composite body and a heat dissipation member were obtained in the same manner as in Example 1, except that a one-layer structure consisting of the mixture was fired without using the copper foil with a dry film and the three-layer structure of dry film/mixture/dry film.

Specifically, a copper powder and diamond particles B (coated with Mo) shown in Table 3 were weighed at 50 vol %:50 vol %, and the weighed powders were uniformly mixed using a V-shape mixer to obtain a mixture.

Next, using an SPS firing device, the obtained mixture was filled in a mold, and sintered by heating at 900° C. for 1 hour under a pressure condition of 30 MPa to obtain a composite one-layer sintered compact (copper-diamond composite body) in which a plurality of diamond particles were dispersed in the copper matrix.

The composite one-layer sintered compact had an outer diameter of 30 mmϕ and a thickness of 3 mm.

Next, a Cu film having a thickness of 30 μm was formed using a sputtering method on each of both surfaces of the copper-diamond composite body, and a heat dissipation member formed of Cu film/copper-diamond composite body/Cu film was obtained.

The same evaluation as that of Example 1 was performed on the obtained composite bodies and the obtained heat dissipation members.

TABLE 3

| | | | Copper-Diamond | | Cu Film/Copper-Diamond | |
|---|---|---|---|---|---|---|
| | Diamond Particles B | | Composite Body | | Composite Body/Cu Film | |
| | Particle | | | Thermal | Cu Film | Thermal |
| | Diameter D₅₀ | Degree of | Flatness | Conductivity | Thickness | Conductivity |
| | (μm) | Sphericity S₅₀ | (μm) | (W/m · k) | (μm) | (W/m · k) |
| Comparative | 200 | 0.9 | 247 | 749 | 30/30 | 582 |
| Example 1 | | | | | | |

Table 1 shows the results that the heat dissipation members of Examples 1 to 9 can realize a higher thermal conductivity than Comparative Example 1.

This application claims priority to Japanese Patent Application No. 2022-074853 filed on Apr. 28, 2022, incorporated herein by reference in its entirety.

### REFERENCE SIGNS LIST

10 metal matrix
12 bonding interface
20, 22 diamond particles
30 copper-diamond composite body
32 coarse particle layer
34, 36 fine particle layer
50 metal film
100 heat dissipation member

1. A heat dissipation member comprising:
a copper-diamond composite body in which a plurality of diamond particles are dispersed in a metal matrix containing copper; and
a metal film that is bonded to at least one surface of the copper-diamond composite body,
wherein in at least one cross section of the heat dissipation member in a stacking direction, the copper-diamond composite body has
a coarse particle layer containing the diamond particles that are coarse particles having a large particle diameter, and
a fine particle layer containing the diamond particles that are fine particles having a smaller particle diameter than the coarse particles, and
has a structure in which the fine particle layer is disposed closer to a bonding surface side between the copper-diamond composite body and the metal film than the coarse particle layer.

2. The heat dissipation member according to claim 1,
wherein when a particle size distribution of the diamond particles is measured using an image particle size distribution measuring device, in a volume particle size distribution of a particle diameter of the diamond particles,
a particle diameter D₅₀ corresponding to a cumulative value of 50% in the coarse particles is more than 100 μm and 300 μm or less, and
a particle diameter D₅₀ corresponding to a cumulative value of 50% in the fine particles is 100 μm or less.

3. The heat dissipation member according to claim 1,
wherein the copper-diamond composite body includes a stacked structure having a first fine particle layer and the coarse particle layer in this order in a layer thickness direction, or a stacked structure having a first fine particle layer, the coarse particle layer, and a second fine particle layer in this order in the layer thickness direction.

4. The heat dissipation member according to claim 3,
wherein a thickness of the fine particle layer is 3 μm or more and 200 μm or less.

5. The heat dissipation member according to claim 1,
wherein a flatness of a bonding surface of the copper-diamond composite body to the metal film is 30 μm or less.

6. The heat dissipation member according to claim 1,
wherein a ten-point average height Rz in a bonding surface of the copper-diamond composite body to the metal film is 20 μm or less.

7. The heat dissipation member according to claim 1,
wherein a thermal conductivity of the copper-diamond composite body is 600 W/m·K or more.

8. The heat dissipation member according to claim 1,
wherein when a particle size distribution of the diamond particles is measured using an image particle size distribution measuring device, in a volume particle size distribution of a degree of sphericity of the diamond particles,
a degree of sphericity S₅₀ corresponding to a cumulative value of 50% in the coarse particles is 0.8 or more.

9. An electronic device comprising:
the heat dissipation member according to claim 1; and
an electronic component provided over the heat dissipation member.
